(19) United States
(12) Patent Application Publication
(10) Pub. No.: US 2023/0178448 A1
(43) Pub. Date: Jun. 8, 2023

(54) OPTICALLY-INDUCED COOLING

(71) Applicant: The Regents of the University of Michigan, Ann Arbor, MI (US)

(72) Inventors: Laura B. Andre, Ann Arbor, MI (US); Long Cheng, Ann Arbor, MI (US); Stephen C. Rand, Ann Arbor, MI (US)

(21) Appl. No.: 18/073,871

(22) Filed: Dec. 2, 2022

Related U.S. Application Data
(60) Provisional application No. 63/285,379, filed on Dec. 2, 2021.

(51) Int. Cl. H01L 23/34

(52) U.S. Cl. CPC H01L 23/34; H01S 3/1625

(57) ABSTRACT

An illumination source is configured to illuminate a medium with light at a wavelength selected based on an emission band of a selected absorption band of the medium. The selected absorption and emission bands being associated with an electric-dipole-allowed transition of the medium. Upon illumination by the light the medium is cooled.

### PRIORITY

This application claims priority to U.S. Provisional Patent Application No. 63/285,379, filed Dec. 2, 2021, bearing Attorney Docket No. 010109-21015P, and titled OPTICALLY-INDUCED COOLING, which is incorporated by reference herein in its entirety.

### STATEMENT REGARDING FEDERALLY SPONSORED RESEARCH OR DEVELOPMENT

This invention was made with government support under FA9550-16-1-0383 awarded by the Air Force Office of Scientific Research. The government has certain rights in the invention.

### BACKGROUND

### Technical Field

The disclosure relates generally to optically-induced cooling or optical refrigeration.

### Brief Description of Related Technology

In recent years, laser cooling has been successfully applied to create new forms of matter (Bose-Einstein condensates), to enable new sensor technologies based on atom interferometry, to perform quantum computation, and to develop quantum memories. Laser cooling to reach cryogenic temperatures in vacuum has been confirmed by the demonstration of a solid state optical cryo-cooler that operates via anti-Stokes fluorescence on forbidden transitions. Also, radiation-balanced lasers have been operated successfully on forbidden transitions. Accordingly, continued improvements in optical cooling technologies will further open new areas of investigation.

### BRIEF DESCRIPTION OF THE DRAWINGS

FIG. 1 shows an example optical cooling system.

FIG. 1A shows an example method for optical cooling.

FIG. 2 shows illustrative example spectra for an optical cooling system based on titanium-doped sapphire.

FIG. 3 shows illustrative example thermal lens spectroscopy signal output displaying waveforms corresponding to heating and cooling.

FIG. 4 shows an example system configuration.

FIG. 5 shows example spectra including wavelengths for selected discrete cooling resonances in Ti:Al₂O₃ for the π-polarization.

FIG. 6 shows example spectra including wavelengths for selected discrete cooling resonances in Ti:Al₂O₃ for the σ-polarization.

### DETAILED DESCRIPTION

Laser cooling of solids has not been so widely employed in photonic device applications because the cooling rate and efficiency demonstrated to date are poorer than in vapors. In condensed matter it has not been possible to implement rapid, efficient cooling with allowed electric-dipole transitions because in general the dense environment of solids causes heating due to configuration relaxation during optical interactions. Forbidden transitions incur no extra heating due to configuration relaxation, and permit lower temperatures to be reached than by any other means to date. On the other hand, optical refrigeration based on forbidden transitions may not necessarily be fast enough for all applications and may not necessarily scale to all payloads.

In various contexts, it may be desirable to cool a target, including some cases, where forbidden-transition-based cooling alone (e.g., without combination with other technologies) may be insufficient. For example, it may be desirable to cool a sensor (or other semiconductor device), act as a coolable substrate for a semiconductor device (for example a Ill-IV and/or II-VI semiconductor device) to create a self-cooled radiation-balanced laser, to refrigerate a target to a cryogenic temperature or below, to cool a target with minimal or no induced vibration as a result of the cooling, and/or to implement other systems where increased cooling power or efficiency is desirable.

In optical cooling, heat can be removed from a target by having a laser induce excitation in the material with laser light including photons of a first energy. The excitations in the material relax over time and release photons of a second energy. If the second energy is higher than the first energy, the excitation-relaxation cycle carries heat away from the target material. To achieve the excitation in the material, an energy-level transition may be used. According to conventional wisdom, optical cooling must avoid the use of electric-dipole-allowed transitions. According to the conventional wisdom, the intense interactions of the electrons with the “cooling” light on electric-dipole-allowed transitions induces in-material vibrations due to configuration relaxation. According to the conventional wisdom, these vibrations would clearly lead to heating that would overwhelm any cooling effect achievable through use of the electric-dipole-allowed transitions.

Contrary to the conventional wisdom, various ones of the techniques and architectures discussed herein implement optical cooling using electric-dipole-allowed transitions. Electric-dipole-allowed transitions may be comparatively faster than forbidden or disallowed transitions, for example some electric-dipole-allowed transitions may have fluorescent relaxation time scales shorter than 10-7 seconds. In some cases, forbidden transitions may have relaxation times longer than 10-3 seconds. As an illustrative example, the 2E-2T2 transition in trivalent titanium ions may have a relaxation time on the scale of 10-6 seconds. Accordingly, cooling via electric-dipole-allowed transitions may be able to increase the rate of cooling by factors of 103-104 or more. Thus, electric-dipole-allowed transitions may have fast relaxation times, e.g., relaxation time faster than 10-4 seconds or other short-time-scale relaxation times.

The short time scales of various electric-dipole-allowed transitions may be shorter than those of impurities or other parasitic heating pathways in a cooled material. Accordingly, as an unexpected result, various ones of these impurities and/or other parasitic heating pathways may be saturated with sufficient cooling illumination and be unable to relax quickly enough to compete with the cooling rate of the electric-dipole-allowed transition. Therefore, in some cases, the heating by unintended impurities through parasitic absorption may be overwhelmed and increased cooling efficiency may be achieved.

In various implementations, cooling wavelengths longer than the mean fluorescence wavelength may be used for illumination of the medium to avoid non-radiative relaxation processes. The quantum efficiency at room temperature may be around 1.0 at such wavelengths for some implementations. This is an effect similar to zero phonon transitions in gamma ray spectroscopy because the excitation of the bulk crystal can be avoided while using electronic transitions of dopant ions.

A further unexpected result is that designing a system to operate using illumination at one or more discrete wavelengths within the emission band increases the cooling power of the system (e.g., relative to operation using wavelengths other than the discrete peaks). In various implementations, the discrete wavelengths at which this increased cooling power can be achieved may be dependent on the material selected for the target cooling medium of the cooling system. Accordingly, in various implementations, the light from an illumination source of an optical cooling system may include light at the one or more material-dependent discrete wavelengths. In some implementations, a medium with a high figure of merit (FOM) may be used. FOM is defined as the ratio of the absorption coefficients at pump and emission wavelengths for a corresponding application of the medium. The FOM may provide a quality measure of the medium for the specific corresponding application, and in some cases, a general quality measure of impurities/defects in the medium. In some cases, a high FOM medium may be used, e.g., a ratio of about 200 or more. Nevertheless, other medium quality measures may be used.

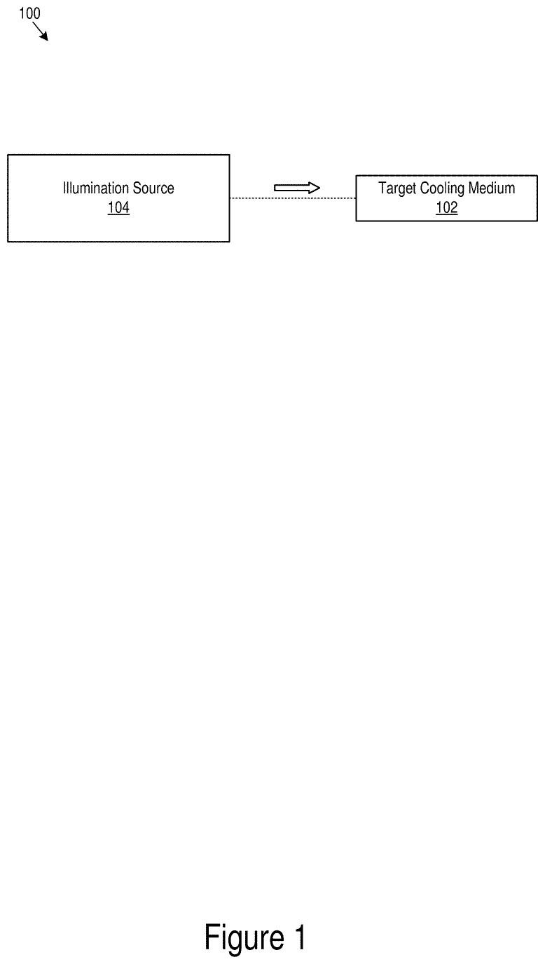

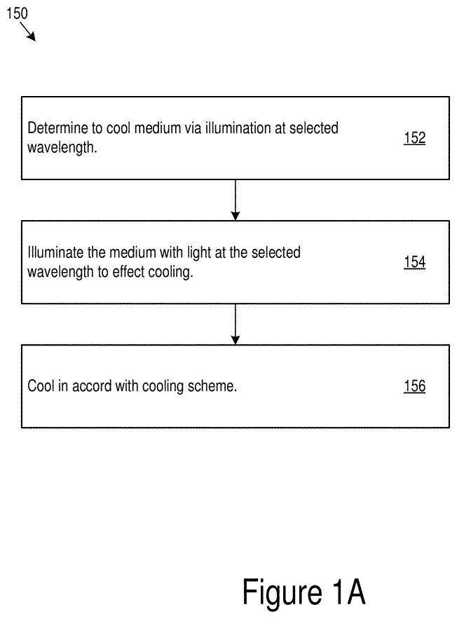

Referring now to FIG. 1, an example optical cooling system (OCS) 100 is shown. The example OCS 100 may include a target cooling medium 102. The target cooling medium 102 may be made up of a material (e.g., with a mass) characterized by an absorption band corresponding to one or more electric-dipole-allowed transitions. The absorption band may have a corresponding fluorescence spectrum (e.g., when the material is excited via illumination within the absorption band). The fluorescence spectrum may be characterized by one or more emission bands.

The OCS 100 may further include an illumination source 104. The illumination source may illuminate the medium with light at a selected wavelength within a portion of the corresponding fluorescence spectrum (including the long-wavelength tail portion). In some cases, the selected wavelength may be greater than an average fluorescence wavelength of the mass for the corresponding fluorescence spectrum. In various implementations, the illumination source 104 may provide light that is spectrally distributed. At least some of the light from the illumination source 104 may be at the selected wavelength, while other portions of the light from the illumination source 104 may be at one or more other wavelengths. Thus, the illumination source may illuminate 104 the medium 102 with light at the selected wavelength, and, in some cases, light at other wavelengths.

In various implementations, the illumination source may include a laser light source. In some cases, a low-entropy light source, such as a single-mode laser may be absorbed to cause anti-Stokes fluorescence in a dispersed form with greater entropy than that of the beam at the time of absorption. Accordingly, the light exiting the material is “hotter” (e.g., more disorganized) and more energetic photon by photon than the beam coming into the material. Hence, the light may carry heat (e.g., via disorganization) out of the material.

Various laser systems may be used as the illumination source, such as titanium sapphire lasers, indium gallium arsenide (InGaAs) lasers, other semiconductor lasers, or various other laser sources. Conversely, titanium sapphire lasers, indium gallium arsenide (InGaAs) lasers, other semiconductor lasers, or various other laser sources may serve as cooling targets or operate in radiation balanced configurations using the cooling architectures and techniques discussed herein. The light source may be continuous-wave or pulsed.

In some cases, the illumination source may further be used to perform laser pumping for population inversion within the material. For example, when a lasing material, such as titanium sapphire, is used as the cooling target, the illumination source may double as a laser pump in addition to providing cooling. The combination of cooling and laser pumping may support a radiation-balanced laser. In some cases, uniform cooling (or non-uniform cooling with the same spatial profile as the pumping power) by the illumination source may mitigate thermal effects normally present due to heating by the pump laser, such as thermal lensing. In some cases, this may allow for higher pumping powers than that achievable without self-cooling or radiation balancing.

In some cases, pumping for lasing in the medium may be provided using a laser pump that is separate from the illumination source used for cooling.

Referring now to FIG. 1A, while continuing to refer to FIG. 1, an example method 150 for optical cooling is shown. At 152, it may be determined to cool a medium 102 using light at a selected wavelength. The wavelength may be selected based on absorption and/or emission bands corresponding to electric-dipole-allowed transitions.

At 154, cooling may be implemented via illumination of the medium by the illumination source 104 with light at the selected wavelength. As discussed above, illumination of the medium 102 via the illumination source 104 may cause excitation of particles in the material which may lead to eventual relaxation via the electric-dipole-allowed transitions. The emissions associated with the electric-dipole-allowed transitions may correspond to higher energy photons than that of the light at the selected wavelength. Thus, the excitation-emission cycle may, on average, carry energy out of the medium (e.g., resulting in cooling).

At 156, the cooling may be executed in accord with a selected cooling scheme. For example, the material may be continuously and/or continually refrigerated by constant and/or repetitive exposure to the light at the selected wavelength. For example, the material may be cooled to a specific temperature and/or held within a specific temperature range. For example, the medium may be cooled to a cryogenic temperature and/or held within a cryogenic temperature range.

For example, the medium may be cooled without net cooling by the cooling process. For example, the cooling may be implemented to counteract (in part) heating done by the illumination source itself. For example, the medium may include a lasing medium pumped by the illumination source. In the absence of cooling, the pumping process generates net heat at a higher level than when the illumination source is also tuned to effect simultaneous cooling. Thus, cooling requirements for such a lasing system (e.g., a radiation “sub-balanced” laser) may be relaxed relative to cooling requirements for systems without tuning for simultaneous cooling.

For example, the material may be cooled in accord with specific timings and/or specific target cooling rates. In some implementations, various criteria for cooling may be set, e.g., initiate cooling when the material exceeds a threshold temperature, cease cooling when the material falls below a threshold temperature; e.g., initiate cooling when the system is exposed to solar (or other celestial) radiation; and/or other cooling criteria.

### Example Implementations

Various illustrative example implementations are included below.

In an illustrative example scenario, a system may perform optical refrigeration (e.g., cooling) of Ti:Sapphire on an allowed 2E-2T2 transition. This constitutes cooling on an electric-dipole-allowed transition in a bulk solid. In some cases, electric-dipole-allowed transitions may support more rapid cooling than forbidden transitions of rare earths. Further, titanium sapphire crystals may serve as a substrate material suitable for the growth of Ill-V semiconductor circuits. This may support imaging arrays with improved signal-to-noise performance at cryogenic temperatures for sensing applications in outer space.

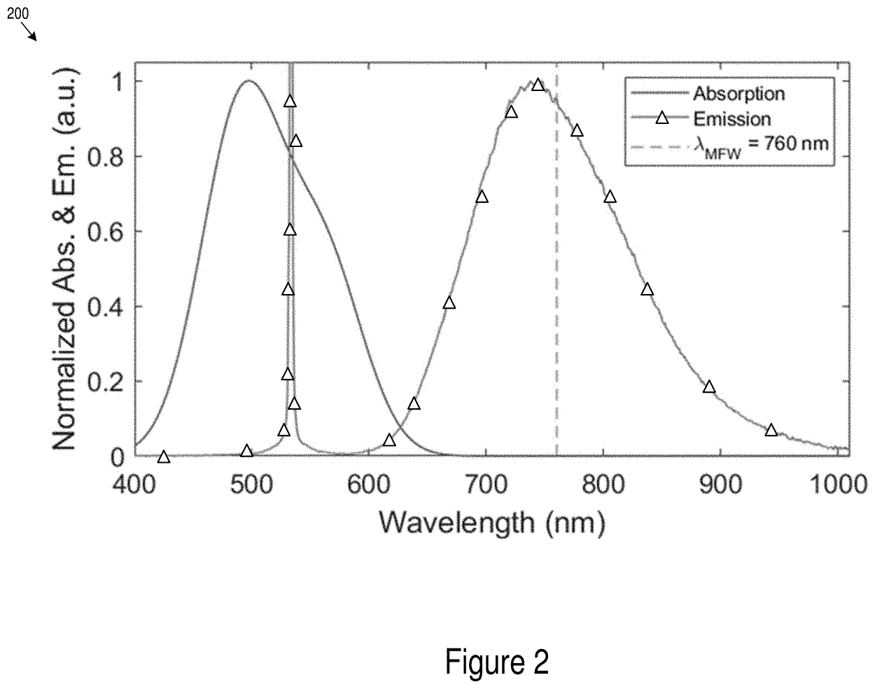

For a proof-of-principle, an example Ti:Sapphire sample was grown using a specialized heat exchange method (HEM). In Ti:Sapphire, a figure of merit (FOM) is defined as the ratio of the absorption coefficients at specific pump and emission wavelengths of 532 nm and 800 nm. This ratio, e.g., (α532 nm/α800 nm), is used as a measure of crystal quality and the potential performance of the a₈₀₀ nm crystal as a laser gain medium. The sample was specifically selected because of its comparatively-high quoted FOM of 844 and was Brewster-cut with dimensions of 4×5×20 mm to avoid the need for coatings on the end faces which can cause heating. Normalized absorption and emission spectra 200 are shown in FIG. 2.

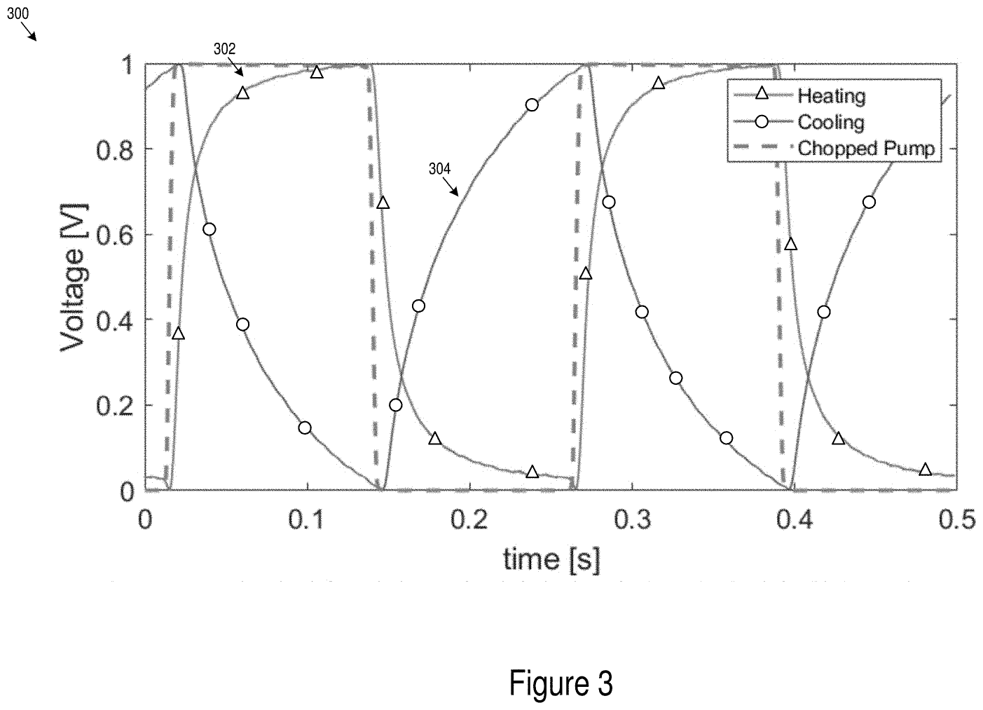

Thermal lens spectroscopy (TLS), demonstrated in the plot 300 of FIG. 3, in a mode-mismatched configuration was used to investigate the thermal characteristics of the sample when the wavelength of the pump light was close to the absorption peak of Ti3+ or in the absorption tail. A weak (e.g., to avoid heating contributions) helium-neon laser, of wavelength λp=633 nm, was used as the probe. For the proof-of-principle, a test was made with the probe while monitoring the sample's temperature with a thermal camera to ensure that the probe power was low enough to avoid heating which would affect the TLS signal. For the illustrative example demonstration, the sample was first pumped with 532 nm light (Coherent Verdi V6) to show heating. The TLS transient for this excitation wavelength 302 shows the expected positive TL signal for a material with ds/dT>0 e.g., increasing optical path length with increasing temperature (T). A continuous-wave, tunable Ti:Sapphire laser (M Squared SolsTiS) was used to pump in the absorption tail (e.g., pumping while tuned to various selected wavelengths longer than the mean fluorescent wavelength, with a line width around 50-100 kHz and the TLS transient was recorded 304. The sign of the TL signal was negative at this wavelength, indicating that the sample was cooling within the pumped interaction volume.

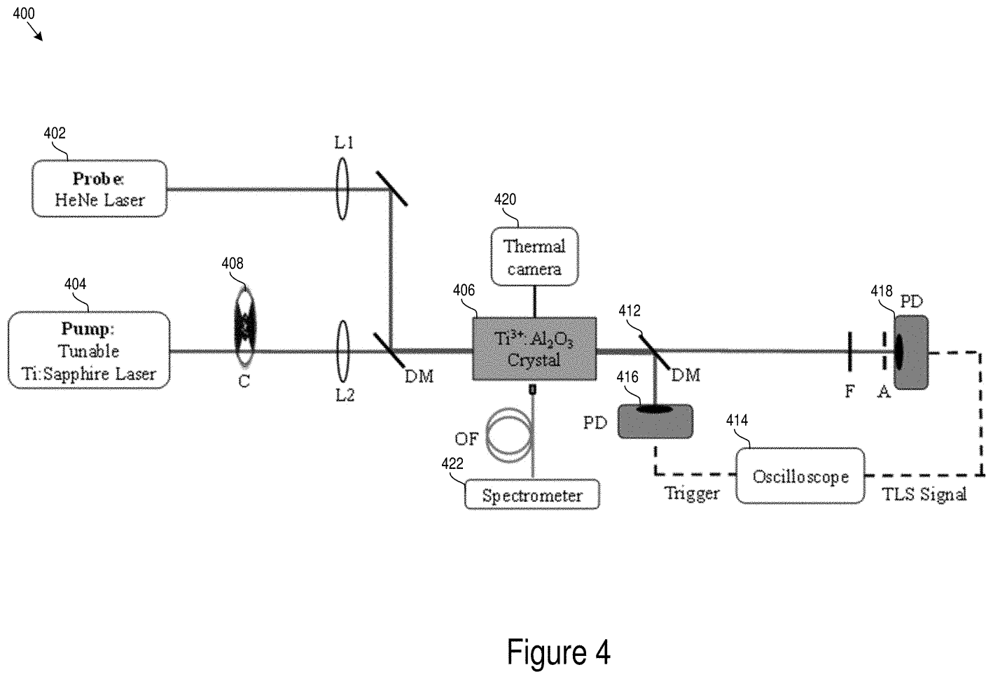

FIG. 4 shows an example system configuration 400 for the proof-of-principle example. In the example system configuration 400, the helium-neon probe 402 and Ti:Sapphire pump 404 illuminate the Ti3+:Al2O3 crystal 406. The illumination from the Ti:Sapphire pump 404 is chopped 408. The illumination from the Ti:Sapphire pump 404 is split off, via dichroic mirror 412, from the helium-neon probe 402 illumination and, via the pump photodiode 416 serves as a trigger signal for the oscilloscope 414 monitoring the helium-neon probe 402 illumination signal, via the probe photodiode 418. The Ti:Sapphire pump may be replaced with a 532 nm laser source (not shown) to demonstrate the contrasting (e.g., heating) signal. The Ti3+:Al2O3 crystal 406 may be further monitored with a thermal camera 420 and a spectrometer 422 to view thermal patterns in the Ti3+:Al2O3 crystal 406 and pump/probe/emission spectra, respectively.

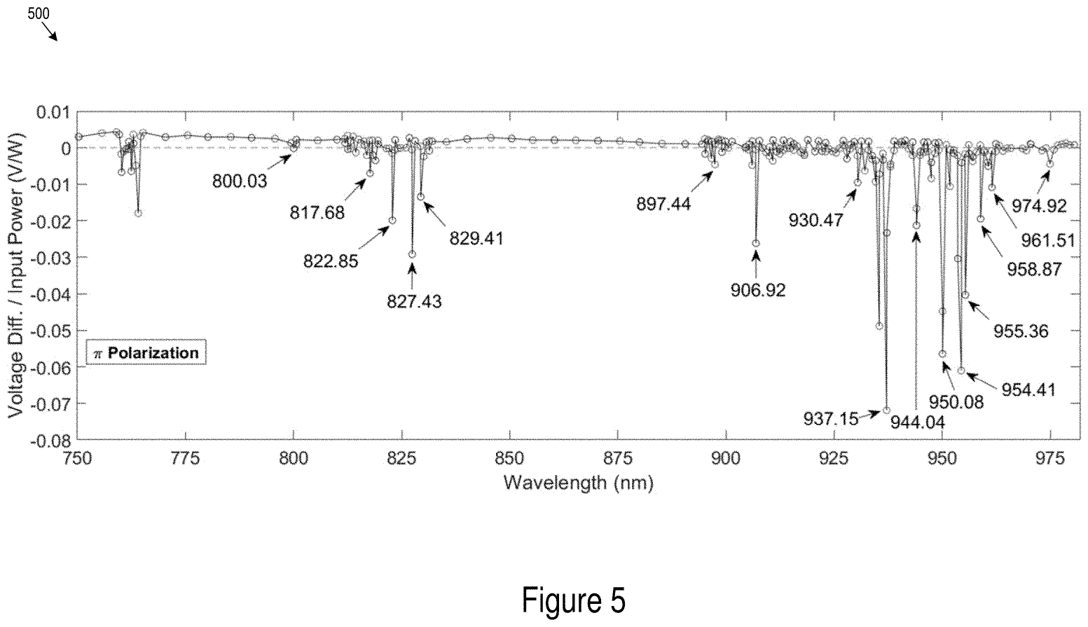

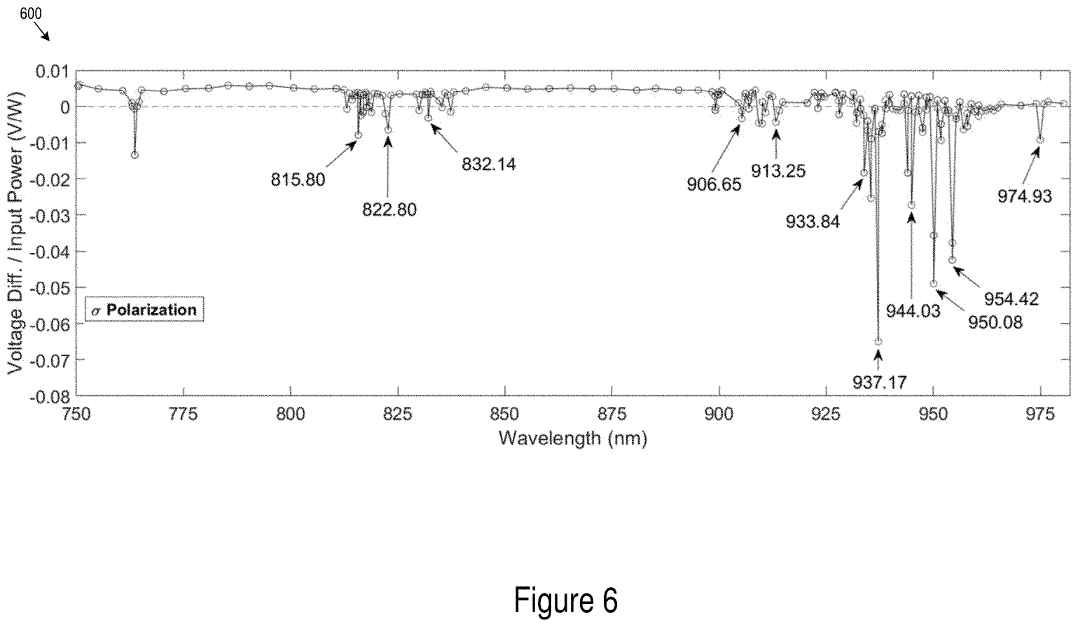

In this illustrative example demonstration, thermal lens spectroscopy has shown a strong reversal of signal polarity between the absorptive and emissive spectral ranges in a sample of Ti:Sapphire with a high figure of merit and Brewster-cut end faces. An unexpected finding was that efficient cooling took place at discrete (material-dependent) wavelengths within the emission band, at wavelengths longer than the mean fluorescent wavelength. FIGS. 5 and 6 show these resonances and Tables 1 and 2 list the assignments of all the absorption transitions at which cooling was observed to electronic and phonon sidebands of Ti3+:Al2O3.

Table 1 shows wavelengths for selected discrete cooling resonances in Ti:Al2O3 for the π-polarization corresponding to the resonances shown in the plot 500 of FIG. 5. Wavenumbers for observed and calculated resonances are subtracted for comparison in the last column on the right. The average discrepancy is given in the bottom row. For this illustrative example, mean fluorescence wavelength was taken to be 760 nm.

TABLE 1
Wavelengths for selected discrete cooling resonances

| l_{obs} | k_{obs} | | | k_{calc} | k_{obs} − k_{calc} |
|---|---|---|---|---|---|
| (nm) | (cm⁻¹) | Initial Level | Site | (cm⁻¹) | (cm⁻¹) |
| 800.03 | 12499.53 | (²A(0), v_{c}) | 4 | 12575.48 | 79.95 |
| 812.84 | 12306.93 | (²A(0), v_{d}) | 2 | 12276.79 | −30.14 |
| 814.39 | 12285.01 | (²A(0), v_{d}) | 3 | 12276.79 | −8.22 |
| 817.86 | 12229.72 | (²A(0), v_{d}) | 4 | 12276.79 | 47.07 |
| 822.85 | 12152.88 | (²A(1), v = 0) | 1 | 11957.89 | −194.99 |
| 827.43 | 12085.61 | (²A(1), v = 0) | 2 | 11957.89 | −127.72 |
| 829.41 | 12056.76 | (²A(1), v = 0) | 3 | 11957.89 | −98.87 |
| 831.39 | 12020.24 | (²A(1), v = 0) | 4 | 11957.89 | −62.35 |
| 897.44 | 11142.81 | (²A(1), v_{d}) | 1 | 11076.89 | −65.91 |
| 906.92 | 11026.33 | (²A(1), v_{d}) | 2 | 11076.89 | 50.56 |
| 930.47 | 10747.26 | (²A(1), v_{d}) | 3 | 11076.89 | 329.64 |
| 937.15 | 10670.65 | (²A(1), v_{d}) | 4 | 11076.89 | 406.24 |
| 944.04 | 10592.77 | (²A(2), v = 0) | 1 | 10547.89 | −44.88 |
| 950.08 | 10525.43 | (²A(2), v = 0) | 2 | 10547.89 | 22.47 |
| 954.41 | 10477.68 | (²A(2), v = 0) | 3 | 10547.89 | 70.22 |
| 955.36 | 10467.26 | (²A(2), v = 0) | 4 | 10547.89 | 80.64 |
| 958.87 | 10428.94 | (²A(2), vₐ) | 1 | 10149.89 | −279.05 |
| 961.51 | 10400.31 | (²A(2), vₐ) | 2 | 10149.89 | −250.41 |
| 974.92 | 10257.25 | (²A(2), vₐ) | 3 | 10149.89 | −107.36 |
| | | | | Average: | −8.04 |

Table 2 shows wavelengths for selected discrete cooling resonances in Ti:Al₂O₃ for 6-polarization corresponding to the resonances shown in the plot 600 of FIG. 6. Wavenumbers for observed and calculated resonances are subtracted for comparison in the last column on the right. The average discrepancy is given in the bottom row. For this illustrative example, mean fluorescence wavelength was taken to be 763 nm.

TABLE 2
Wavelengths for selected discrete cooling resonances

| λ_{obs} | k_{obs} | | | k_{calc} | k_{obs} − k_{calc} |
|---|---|---|---|---|---|
| (nm) | (cm⁻¹) | Initial Level | Site | (cm⁻¹) | (cm⁻¹) |
| 815.80 | 12257.91 | (²A(0), v_{d}) | 4 | 12199.56 | −58.35 |
| 822.80 | 12153.62 | (²A(1), v = 0) | 3 | 11906.16 | −247.46 |
| 832.14 | 12017.21 | (²A(1), v = 0) | 4 | 11906.16 | −111.05 |
| 906.65 | 10993.24 | (²A(1), v_{d}) | 1 | 10999.56 | 6.32 |
| 913.25 | 10949.90 | (²A(1), v_{d}) | 2 | 10999.56 | 49.66 |
| 933.84 | 10708.47 | (²A(1), v_{d}) | 3 | 10999.56 | 291.09 |
| 937.17 | 10670.42 | (²A(1), v_{d}) | 4 | 10999.56 | 329.14 |
| 944.03 | 10592.88 | (²A(2), v = 0) | 1 | 10496.16 | −96.72 |
| 950.08 | 10525.43 | (²A(2), v = 0) | 2 | 10496.16 | −29.27 |
| 954.42 | 10477.57 | (²A(2), v = 0) | 3 | 10496.16 | 18.59 |
| 957.90 | 10439.50 | (²A(2), v = 0) | 4 | 10496.16 | 56.66 |
| 974.93 | 10257.15 | (²A(2), vₐ) | 4 | 10111.17 | −14.98 |
| | | | | Average: | 4.82 |

It is possible to cool crystals optically on electric-dipole-allowed transitions with very large relaxational (Stokes) shifts between absorption and emission wavelengths. Successful cooling of sapphire is primarily mediated by discrete absorptive transitions involving electronic and optical phonon sublevels in the ground state of Ti3+. This demonstration may be significant for applications in vacuum or space since this material is a valid substrate for radiation-hard Ill-V semiconductor circuitry appropriate for infrared sensing and other applications.

Various example implementations have been included for illustration. Other implementations are possible. Table 3 shows various examples.

TABLE 3
Examples

1. A method includes:
cooling a medium including a mass characterized by a selected
absorption band of one or more electric-dipole-allowed transitions,
the selected absorption band having a corresponding fluorescence
spectrum by:
illuminating the medium with light at a selected wavelength within
(or near) an emission band of the corresponding fluorescence
spectrum, where:
optionally, the selected wavelength is greater than an average
fluorescence wavelength of the mass for the corresponding
fluorescence spectrum; and
optionally, the selected wavelength is in resonance with an electronic
transition, an
optical phonon sideband absorption, or an acoustic phonon sideband;
and
optionally, the method is in accord with any other example in this
table.
2. A system including:
a medium including a mass characterized by a selected absorption
band of one or more electric-dipole-allowed transitions, the selected
absorption band having a corresponding fluorescence spectrum; and
an illumination source configured to illuminate the medium with light
at a selected wavelength within (or near) an emission band of the
corresponding fluorescence spectrum, where:
optionally, the selected wavelength is greater than an average
fluorescence wavelength of the mass for the corresponding
fluorescence spectrum; and
optionally, the selected wavelength is in resonance with an electronic
transition, an optical phonon sideband absorption, or an acoustic
phonon sideband; and
optionally, the system is in accord with any other example in this
table.
3. The method or system of any of the other examples in this table,
where the light includes:
optionally, visible and/or near infrared light;
optionally, coherent light;
optionally, laser light;
optionally, continuous wave laser light;
optionally, pulsed laser light;
optionally, light characterized by a bandwidth less than 1 Mhz, 100
kHz, 50 kHz, and/or narrower bandwidth;
optionally, single-mode laser light;
optionally, titanium sapphire laser light;
optionally, indium gallium arsenide (InGaAs) laser light;
optionally, with laser light a wavelength longer than 760 nm;
optionally, with laser light a wavelength longer than 770 nm;
optionally, with laser light a wavelength shorter than 770 nm;
optionally, with laser light a wavelength longer than 820 nm;
optionally, with laser light a wavelength shorter than 820 nm;
optionally, with laser light a wavelength longer than 830 nm;
optionally, with laser light a wavelength shorter than 830 nm;
optionally, with laser light a wavelength longer than 850 nm;
optionally, with laser light a wavelength shorter than 850 nm;
optionally, with laser light a wavelength longer than 900 nm;
optionally, with laser light a wavelength shorter than 900 nm;
optionally, with laser light a wavelength longer than 950 nm;
optionally, with laser light a wavelength shorter than 950 nm;
optionally, with laser light a wavelength longer than 1000 nm;
optionally, with laser light a wavelength shorter than 1000 nm;
optionally, polarized light, (e.g., polarized with reference to a
material axis): optionally, σ-polarized light; and
optionally, π-polarized light; and
optionally, illumination selected to perform cooling using one or
more discrete material-dependent cooling wavelengths, where:
optionally, the one or more discrete material-dependent cooling
wavelengths include any of (or any grouping of) the discrete
wavelengths listed in Table 1 and/or Table 2 (above).
4. The method or system any of the other examples in this table,
where the mass includes:
optionally, a bulk solid;
optionally, a crystal, such as a Brewster cut crystal;
optionally, a glass;
optionally, a liquid;
optionally, a lasing medium;
optionally, a doped material, where optionally the dopant includes a
transition metal ion;
optionally, a doped material, where optionally the dopant includes
a rare earth ion;
optionally, a corundum crystal (e.g., ruby, sapphire, or other
corundum);
optionally, a garnet crystal, such as yttrium aluminum garnet;
optionally, an oxide crystal;
optionally, a low-impurity material;
optionally, a material with low excited-state absorption;
optionally, a titanium sapphire crystal, e.g., a sapphire crystal doped
with ionic titanium;
optionally, a material with a high figure of merit relevant to laser
operation, e.g., for laser crystal the figure of merit may include
the ratio of absorption coefficients at the pumping and lasing
wavelengths:
$\frac{{α}_{pumping}}{{α}_{lasing}} ;$
optionally, a material with (e.g., an optimized) balance of impurities
to dopant, where dopants are set to a high concentration that is
achievable without increasing impurities, for example to achieve
a figure of merit above a given threshold: 300, 500, 700, 800 or
other threshold;
optionally, a material with an excitation characterized by fast
relaxation time, where:
optionally, a “fast” relaxation time is defined relative to relaxation
times/effective cycle times of parasitic effects due to material
impurities, phonons, material vibrations, and/or other heat generating
effects;
optionally, a “fast” transition includes a transition with a relaxation
time of 10⁻³ seconds or faster.
5. The method or system of any of the other examples in this table,
further including heating the medium, where:
optionally, heating the medium includes pumping the medium to
support lasing in the medium;
optionally, heating the medium includes placing the medium in
contact with a sample that is warmer than a current temperature of the
medium.
6. The method or system of any of the other examples in this table,
where cooling the medium includes:
cooling the medium to a cryogenic temperature or below, e.g., 77
kelvin or below; and cooling the medium to temperatures below
those available via thermoelectric cooling, e.g., 145 kelvin or below.
7. The method or system of any of the other examples in this table,
where the electric-dipole-allowed transition includes a ²E-²T₂
transition.
8. The method or system of any of the other examples in this table,
where the medium includes a substrate for a III-V semiconductor
circuit.
9. The method or system of any of the other examples in this table,
further including operating medium as a lasing medium for a
radiation balanced (e.g., self-cooling) laser, where:
optionally, operating medium as a lasing medium includes pumping
(e.g., for lasing and/or cooling) the medium with an indium gallium
arsenide (InGaAs) laser or other near infrared laser;
optionally, operating medium as a lasing medium includes pumping
(e.g., for lasing and/or cooling) the medium with the illumination
source;
optionally, operating medium as a lasing medium includes pumping
(e.g., for lasing and/or cooling) the medium with a source with output
around 820 nm-870 nm.
10. The method or system of any of the other examples in this table,
further including implementing the medium as a refrigerated test bed
for experiments.
11A. The method or system of any of the other examples in this table,
further including implementing the medium as a refrigeration device
for a sensor in outer space, where:
optionally, the sensor includes an imaging array;
optionally, the sensor includes a semiconductor imaging array.
11B. The method or system of any of the other examples in this
table, further including implementing the medium as a refrigeration
device for a sensor in a vacuum, where:
optionally, the sensor includes an imaging array;
optionally, the sensor includes a semiconductor imaging array.
11C. The method or system of any of the other examples, further
including implementing the medium as a refrigeration device for
a transmitter in outer space, where:
optionally, the transmitter includes a semiconductor circuit;
optionally, the transmitter includes an electronic circuit;
optionally, the transmitter includes a MEMS circuit.
11D. The method or system of any of the other examples in this table,
further including implementing the medium as a refrigeration device
for a transmitter in a vacuum, where:
optionally, the transmitter includes a semiconductor circuit;
optionally, the transmitter includes an electronic circuit;
optionally, the transmitter includes a MEMS circuit.
12. The method or system of any of the other examples in this table,
where illuminating the medium includes illuminating the medium
with a low entropy light source (e.g., a “cold” light source -- a narrow-
line, high-coherence, and spatially-organized beam) such that the
material disperses the light source, thereby increasing the entropy
of light exiting the medium (e.g., making the light exiting the
medium “hot”).
13. The method or system of any of the other examples in this table,
further including using the light-based cooling technique to isolate a
cooled target from vibrations from a power source, mechanical
elements, or other vibration sources.
14. The method or system of any of the other examples in this table,
further including tuning the selected wavelength to a wavelength at a
low-energy (high wavelength) end of the absorption band to avoid
heating due to configuration relaxation, where:
optionally, tuning the selected wavelength includes tuning to a tail
of the absorption band.
15. The method or system of any of the other examples in this table,
where illuminating the medium includes saturating one or more
parasitic background effects (e.g., from impurities, phonons, or other
parasitic effects) to increase cooling efficiency or cooling rate or to
reach a lower minimum temperature.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A method includes:
cooling a medium including a mass characterized by a selected absorption band of one or more electric-dipole-allowed transitions, the selected absorption band having a corresponding fluorescence spectrum by:
illuminating the medium with light at a selected wavelength for an emission band of the corresponding fluorescence spectrum, where:
the selected wavelength is greater than an average fluorescence wavelength of the medium for the corresponding fluorescence spectrum.

2. The method of claim 1, further including pumping the medium to support lasing in the medium.

3. The method of claim 2, further including operating the medium as a lasing medium for a radiation balanced laser.

4. The method of claim 1, where cooling the medium includes cooling the medium to a cryogenic temperature or below.

5. The method of claim 1, further including implementing the medium as a refrigerated test bed for experiments.

6. The method of claim 1, where the medium includes a substrate for a semiconductor circuit.

7. The method of claim 1, where the medium includes a titanium sapphire crystal.

8. The method of claim 1, where illuminating the medium includes illuminating the medium with a low entropy light source.

9. The method of claim 1, where the selected wavelength includes 950 nm±20 nm.

10. The method of claim 1, further including implementing the medium as a refrigeration device for a semiconductor sensor.

11. The method of claim 1, where illuminating the medium includes saturating one or more parasitic background effects intrinsic to the medium.

12. The method of claim 1, where the medium includes a material with an excitation characterized by a fast relaxation time.

13. A system including:
a medium including a mass characterized by a selected absorption band of one or more electric-dipole-allowed transitions, the selected absorption band having a corresponding fluorescence spectrum; and
an illumination source configured to illuminate the medium with light at a selected wavelength for an emission band of the corresponding fluorescence spectrum, where:
the selected wavelength is greater than an average fluorescence wavelength of the medium for the corresponding fluorescence spectrum.

14. The system of claim 13, where the illumination source is further configured to pump the medium to support lasing in the medium.

15. The system of claim 14, where the illumination source is further configured to pump the medium to operate the medium as a lasing medium for a radiation balanced laser.

16. The system of claim 13, where the illumination source is further configured to illuminate the medium to cool the medium to a cryogenic temperature or below.

17. The system of claim 13, further including sensor circuitry, where:
the medium includes a refrigeration device for the sensor circuitry.

18. The system of claim 13, where the medium includes a substrate for a semiconductor circuit.

19. The system of claim 13, where the medium includes a titanium sapphire crystal.

20. A device including:
an illumination source configured to illuminate a medium with light to effect cooling within the medium; and
control circuitry configured to cause the illumination source to generate the light at a selected wavelength for an emission band of a fluorescence spectrum of a selected absorption band of one or more electric-dipole-allowed transitions of the medium, where the selected wavelength is longer than an average fluorescence wavelength of the medium for the fluorescence spectrum.
